(19) United States
(12) Patent Application Publication
(10) Pub. No.: US 2016/0063925 A1
(43) Pub. Date: Mar. 3, 2016

(54) CURRENT SENSING DEVICE OF DISPLAY PANEL AND ORGANIC LIGHT EMITTING DISPLAY DEVICE HAVING THE SAME

(71) Applicant: SAMSUNG DISPLAY CO., LTD., Yongin-City (KR)

(72) Inventors: Jong-Man Bae, Seoul (KR); Byeong-Doo Kang, Cheonan-si (KR); Jin-Woo Kim, Hwaseong-si (KR)

(21) Appl. No.: 14/616,631

(22) Filed: Feb. 6, 2015

(30) Foreign Application Priority Data
Sep. 3, 2014 (KR) 10-2014-0117278

(51) Int. Cl. G09G 3/32; G01R 19/25

(52) U.S. Cl. CPC G09G 3/3283; G01R 19/25; G09G 3/3266; G09G 2310/08; G09G 2310/0272; G09G 2310/027; G09G 2320/0233; G09G 2320/045; G09G 2320/0626; G09G 2320/0295; G09G 2310/0294

(57) ABSTRACT

A current sensing device includes a variable resistor control unit calculating an estimated driving current based on image data to be displayed on the display panel and outputting variable resistor control signal corresponding to a current range that includes the estimated driving current, a current sensing unit sensing a driving current provided to pixels and outputting a sensing voltage corresponding to the driving current, a sensing voltage calculating unit changing an integral gain according to the variable resistor control signal and integrating the sensing voltage, and a calculating control unit controlling an operation of the sensing voltage calculating unit.

### CROSS-REFERENCE TO RELATED APPLICATION

This application claims priority to and the benefit of Korean Patent Application No. 10-2014-0117278, filed on Sep. 3, 2014 in the Korean Intellectual Property Office (KIPO), the contents of which are incorporated herein in its entirety by reference.

### BACKGROUND

1. Field

Example embodiments relate generally to a current sensing device of a display panel and an organic light emitting display device having the same.

2. Description of the Related Art

Organic light emitting display (OLED) device displays visually transmit information including images and characters by using light generated when holes and electrodes are combined with each other at an organic light emitting layer interposed between an anode and a cathode. OLED device displays have been highlighted as a next-generation display device because they have favorable characteristics such as improved side viewing angle, a relatively rapid response speed, a thin profile, low power consumption, etc.

Over time, however, an organic light emitting diode included in pixels of OLED device may be degraded, and a brightness of the pixels may decrease. Accordingly, a method and system for compensating for a degradation of the organic light emitting diode may improve the viewing experience of OLED device displays.

### SUMMARY

Some example embodiments provide a current sensing device of a display panel capable of accurately detecting a driving current that flows through a pixel.

Some example embodiments provide an organic light emitting display device capable of accurately detecting a driving current that flows through a pixel.

According to an aspect of example embodiments, a current sensing device of a display panel may include a variable resistor control unit configured to receive image data to be displayed on the display panel, to calculate an estimated driving current flowing through a plurality of pixels included in the display panel based on the image data, and to output a variable resistor control signal corresponding to a current range including the estimated driving current, a current sensing unit configured to sense a driving current provided to the pixels while the image data is displayed on the display panel and to output a sensing voltage corresponding to the driving current, a sensing voltage calculating unit configured to change an integral gain according to the variable resistor control signal and to integrate the sensing voltage, and a calculating control unit configured to control an operation of the sensing voltage calculating unit in response to a calculating control signal.

In example embodiments, the sensing voltage calculating unit may include an integrator including a first input terminal, a second input terminal, and an output terminal, a first resistor between the calculating control unit and the first input terminal, a second resistor between the first input terminal and the output terminal, a third resistor between the second input terminal and a ground connection and implemented as a digital variable resistor, a fourth resistor between the second input terminal and the output terminal, and a capacitor between the first input terminal and the ground connection.

In example embodiments, wherein a resistance of the third resistor may be changed according to the variable resistor control signal.

In example embodiments, the calculating control unit may include a first switching transistor configured to transmit the sensing voltage to the sensing voltage calculating unit in response to the calculating control signal, and a second switching transistor configured to discharge the capacitor in response to the calculating control signal.

In example embodiments, the first switching transistor may be implemented as a P-channel Metal Oxide Semiconductor (PMOS) transistor, and the second switching transistor may be implemented as an N-channel Metal Oxide Semiconductor (NMOS) transistor.

In example embodiments, the sensing voltage may be integrated based on the integral gain when the calculating control signal having a logic low level is provided, and the capacitor may be discharged when the calculating control signal having a logic high level is provided.

In example embodiments, the first switching transistor may be implemented as an N-channel Metal Oxide Semiconductor (NMOS) transistor, and the second switching transistor may be implemented as a P-channel Metal Oxide Semiconductor (PMOS) transistor.

In example embodiments, the sensing voltage may be integrated based on the integral gain when the calculating control signal having a logic high level is provided, and the capacitor may be discharged when the calculating control signal having a logic low level is provided.

In example embodiments, the variable resistor control unit may include an estimated driving current calculating unit configured to calculate the estimated driving current of the image data per frame and a variable resistor control signal output unit configured to output the variable resistor control signal corresponding to the current range including the estimated driving current.

In example embodiments, the variable resistor control signal output unit may include a lookup table that stores the variable resistor control signal corresponding to the current range including the estimated driving current.

In example embodiments, the current sensing unit may include a detecting resistor configured to generate a detecting voltage corresponding to the driving current provided to the pixels and an amplifier configured to amplify the detecting voltage to output an amplified detecting voltage as the sensing voltage.

According to an aspect of example embodiments, an organic light emitting display device may include a display panel including a plurality of pixels, a data driving unit configured to provide a data signal to the display panel, a current sensing unit configured to calculate an estimated driving current flowing through the pixels based on image data to be displayed on the display panel, to detect a sensing voltage corresponding to a driving current flowing through the pixels while the image data is displayed on the display panel, and to calculate the sensing voltage by changing an integral gain according to a current range including the estimated driving current, and a timing control unit configured to control the data driving unit, the scan driving unit, and the current sensing unit.

In example embodiments, the current sensing unit may include a variable resistor control unit configured to receive the image data to be displayed on the display panel, to calculate the estimated driving current flowing through the pixels based on the image data, and to output a variable resistor control signal corresponding to the current range including the estimated driving current, a current sensing unit configured to sense the driving current provided to the pixels while the image data is displayed on the display panel and to output the sensing voltage corresponding to the driving current, a sensing voltage calculating unit configured to change the integral gain according to the variable resistor control signal and to integrate the sensing voltage, and a calculating control unit configured to control an operation of the sensing voltage calculating unit in response to a calculating control signal.

In example embodiments, the sensing voltage calculating unit may include an integrator including a first input terminal, a second input terminal, and an output terminal, a first resistor coupled between the calculating control unit and the first input terminal, a second resistor coupled between the first input terminal and the output terminal, a third resistor coupled between the second input terminal and a ground connection and implemented as a digital variable resistor, a fourth resistor coupled between the second input terminal and the output terminal, and a capacitor coupled between the first input terminal and the ground connection.

In example embodiments, a resistance of the third resistor may be changed according to the variable resistor control signal.

In example embodiments, the calculating control unit may include a first switching transistor configured to transmit the sensing voltage to the sensing voltage calculating unit in response to the calculating control signal, and a second switching transistor configured to discharge the capacitor in response to the calculating control signal.

In example embodiments, the variable resistor control unit may include an estimated driving current calculating unit configured to calculate the estimated driving current of the image data per frame and a variable resistor control signal output unit configured to output the variable resistor control signal corresponding to the current range including the estimated driving current.

In example embodiments, the variable resistor control signal output unit may include a lookup table that stores the variable resistor control signal corresponding to the current range including the estimated driving current.

In example embodiments, the current sensing unit may include a detecting resistor configured to generate a detecting voltage corresponding to the driving current provided to the pixels and an amplifier configured to amplify the detecting voltage to output an amplified detecting voltage as the sensing voltage.

In example embodiments, the current sensing unit may be coupled to the timing control unit or be included in the timing control unit.

Therefore, a current sensing device and an organic light emitting display device having the same according to example embodiments may accurately detecting a driving current flowing through pixels when image data is displayed on a display panel by calculating an estimated driving current flowing through the pixels based on the image data that will be displayed on the display panel and changing an integral gain of an integrator based on a current range that includes the estimated driving current.

### BRIEF DESCRIPTION OF THE DRAWINGS

Illustrative, non-limiting example embodiments will be more clearly understood from the following detailed description taken in conjunction with the accompanying drawings.

FIG. 1 is a block diagram illustrating a current sensing device according to example embodiments.

FIG. 2 is a circuit diagram illustrating the current sensing device of FIG. 1.

FIG. 3 is a variable resistor control unit that is included in the current sensing device of FIG. 1.

FIG. 4 is a diagram illustrating an example of a lookup table that is included in the variable resistor control unit of FIG. 3.

FIGS. 5A and 5B are circuit diagrams illustrating examples of a calculating control unit that is included in the current sensing device of FIG. 1.

FIG. 6 is a block diagram illustrating an organic light emitting display device according to example embodiments.

FIG. 7 is a block diagram illustrating an electronic device that includes the organic light emitting display device of FIG. 6.

FIG. 8 is a diagram illustrating an example of the electronic device that is implemented as a smart phone.

### DETAILED DESCRIPTION

Hereinafter, aspects of example embodiments of the present invention will be explained in some detail with reference to the accompanying drawings.

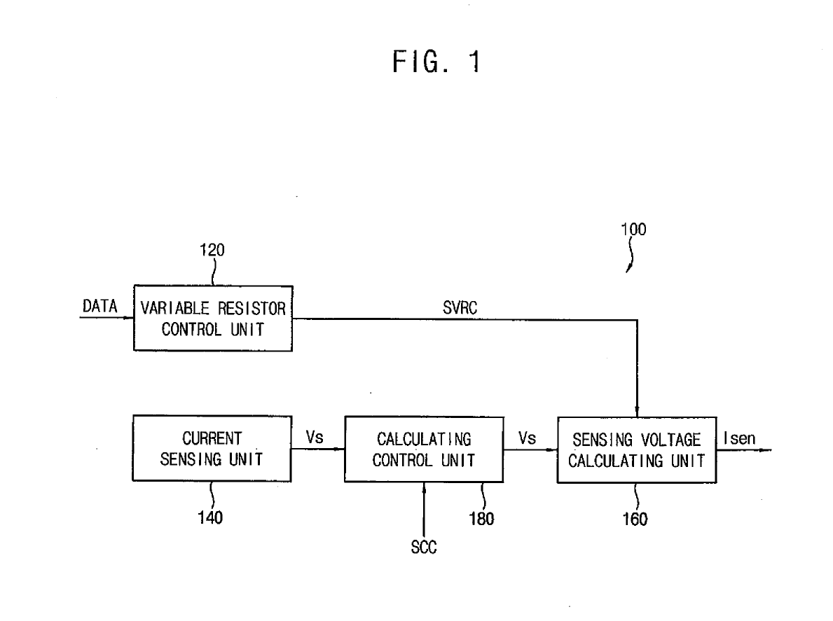

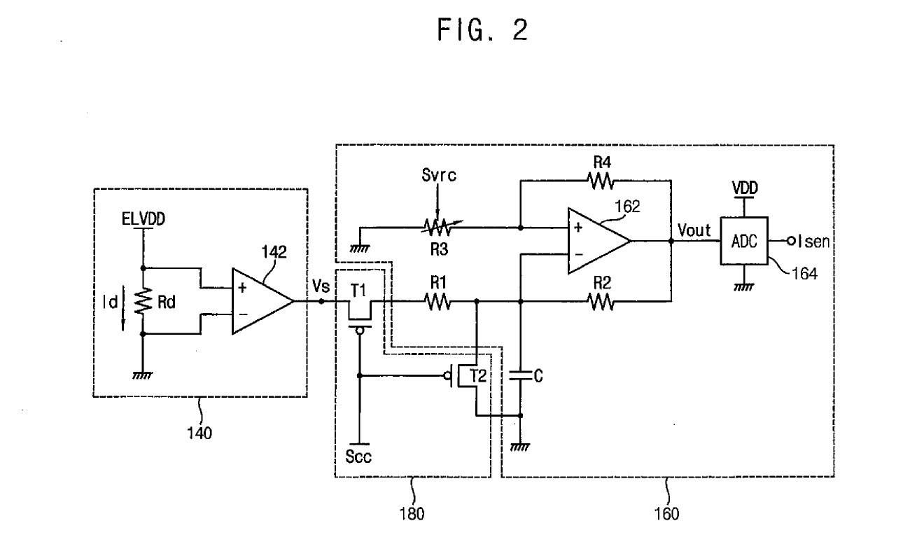

FIG. 1 is a block diagram illustrating a current sensing device according to example embodiments and FIG. 2 is a circuit diagram illustrating the current sensing device of FIG. 1.

Referring to FIGS. 1 and 2, a current sensing device 100 may include a variable resistor control unit 120, a current sensing unit 140, a sensing voltage calculating unit 160, and a calculating control unit 180.

The variable resistor control unit 120 may receive image data DATA to be displayed on a display panel, calculate an estimated driving current flowing through a plurality of pixels included in the display panel based on the image data DATA, and output a variable resistor control signal Svrc corresponding to a current range that includes the estimated driving current. The driving current flowing through the pixels of the display panel may be changed based on the image data DATA. The variable resistor control unit 120 may receive the image data DATA per frame and calculate the estimated driving current. For example, the variable resistor control unit 120 may receive image data of an (N+1)th frame while image data of an (N)th frame is displayed on the display panel and calculate an estimated driving current based on the image data of the (N+1)th frame, where N is an integer greater than 1. The variable resistor control unit 120 may output the variable resistor control signal Svrc corresponding to the current range that includes the estimated driving current of the (N+1)th frame. The variable resistor control unit 120 may store the variable resistor control signal Svrc corresponding to the current range that includes the estimated driving current into a lookup table (LUT). The variable resistor control unit 120 may select the variable resistor control signal Svrc corresponding to the current range that includes the estimated driving current in the lookup table and output the variable resistor control signal Svrc to the sensing voltage calculating unit 160 per frame. It should be understood that the lookup table can be implemented by any storage device capable of storing the load amount corresponding to the digital signals.

The current sensing unit 140 may sense the driving current provided to the pixels while the image data DATA is displayed on the display panel and output a sensing voltage Vs corresponding to the driving current. The current sensing unit 140 may generate a detecting voltage corresponding to the driving current provided to the pixels while the image data DATA is displayed on the display panel, amplify the detecting voltage, and output the amplified detecting voltage as the sensing voltage Vs. In some example embodiments, the current sensing unit 140 may be coupled to a line that provides a high power voltage ELVDD and measure the current that flows to the pixels. In other example embodiments, the current sensing unit 140 may be coupled to a line that provides a low power voltage ELVSS and measure the current that flows to the pixels. Referring to FIG. 2, the current sensing unit 140 may include a detecting resistor Rd to detect the driving current provided to the pixels and an amplifier 142. The detecting resistor Rd may be arranged on a power voltage supply line. The detecting resistor Rd may generate the detecting voltage corresponding to the driving current Id flowing through the power voltage supply line. The detecting resistor Rd may have a low resistance such that a voltage or a current provided to the pixels through the power voltage supply line may not be substantially affected by the detecting resistor Rd. In some example embodiments, the power voltage supply line may be a line that provides the high power voltage ELVDD, and the detecting resistor may generate the detecting voltage corresponding to the driving current Id flowing from the high power supply line to the pixels. In other example embodiments, the power voltage supply line may be a line that provides the low power voltage ELVSS, and the detecting resistor may generate the detecting voltage corresponding to the driving current Id flowing from the low power supply line to the pixels. The amplifier 142 may amplify the detecting voltage generated by the detecting resistor Rd and output the amplified detecting voltage as the sensing voltage Vs. In some example embodiments, the amplifier 142 may be a differential amplifier. In other example embodiments, the amplifier 142 may be a single ended amplifier. Although FIG. 2 illustrates an example where each current sensing unit 140 includes the amplifier 142, in some example embodiments, each current sensing unit 140 may be implemented without the amplifier 142. The sensing voltage Vs generated from the current sensing unit 140 may be provided to the sensing voltage calculating unit 160 through the calculating control unit 180.

The sensing voltage calculating unit 160 may change an integral gain of an integrator 162 according to the variable resistor control signal Svrc and integrates the sensing voltage Vs. Referring to FIG. 2, the sensing voltage calculating unit 160 may include the integrator 162, a first resistor R1, a second resistor R2, a third resistor R3, a fourth resistor R4, and a capacitor C. The integrator 162 may include a first input terminal, a second input terminal, and an output terminal. The first resistor R1 may be coupled between the calculating control unit 180 and a first input terminal of the integrator 162. The second resistor R2 may be coupled between the first input terminal of the integrator 162 and the output terminal. The third resistor R3 may be coupled between the second input terminal of the integrator 162 and a ground connection (or a power supply supplying a ground voltage). The fourth resistor R4 may be coupled between the second input terminal of the integrator 162 and the output terminal. The capacitor may be coupled between the first input terminal of the integrator 162 and the ground connection. The output voltage Vout from the integrator 162 of the sensing voltage calculating unit 160 may be calculated according to [Equation 1] below,

$$Vout = \frac{( 1 + \frac{R 4}{R 3} )}{R 1 \times C} \times {\int }_{0}^{T} Vs ( t ) d t , \\ ( R 1 = \frac{R 2 \times R 3}{R 4} ) \qquad Equation 1$$

Here, the third resistor R3 may be implemented as a digital variable resistor. A resistance of the third resistor R3 may be changed according to the variable resistor control signal Svrc. The integral gain of the integrator 162 may be changed as the resistance of the third resistor R3 is changed. That is, the integral gain of the integrator 162 included in the sensing voltage calculating unit 160 may be changed according to the current range that includes the estimated driving current calculated in the variable resistor control unit 120, and the sensing voltage Vs output from the current sensing unit 140 may be integrated by the integral gain. The sensing voltage calculating unit 160 may further include an analog to digital converter (ADC) 164. The analog-digital converter 164 may receive an output voltage Vout from the integrator 162 and convert the output voltage Vout into the digital sensing current Isen.

The calculating control unit 180 may control an operation of the sensing voltage calculating unit 160 in response to a calculating control signal Scc. Referring to FIG. 2, the calculating control unit 180 may include a first switching transistor T1 that transmits the sensing voltage Vs output from the current sensing unit 140 in response to the calculating control signal Scc into the sensing voltage calculating unit 160 and a second switching transistor T2 that discharges the capacitor C of the sensing voltage calculating unit 160 in response to the calculating control signal Scc. In some example embodiments, when the first switching transistor T1 turns on, the sensing voltage Vs may be transmitted to the sensing voltage calculating unit 160 and be integrated by the integral gain. Here, the second switching transistor T2 may turn off. In other example embodiments, when the second switching transistor T2 turns off, the capacitor C of the sensing voltage calculating unit 160 may be discharged. Here, the first switching transistor T1 may turn off.

Whether a degradation of the display panel occurs may be determined by a variation of the driving current as time passes. Generally, the driving current of the organic light emitting display device that is driven in a digital driving method may be detected by integrating the driving current using a current sensing device that includes an integrator. The current sensing device may include an amplifier, a resistor, a capacitor, an analog-digital converter, etc. An output value of the current sensing device may be changed by errors of above elements. When a current sensing device detects the driving current of the organic light emitting device driven in the digital driving method, the variation of the driving current may not be detected because of the errors of the elements. For example, when the driving current is included in a low current range and the variation of the output value of the current sensing device is smaller than the variation of the driving current, a current sensing device may not detect the variation of the driving current because of the errors of the elements.

However, as described above, the current sensing device 100 according to example embodiments may calculate the estimated driving current flowing through the pixels based on the image data DATA that will be displayed on the display panel and change the integral gain of the integrator 162. Therefore, the current sensing device 100 of FIG. 1 may accurately detect the variation of the driving current flowing through the pixels when the image data DATA is displayed on the display panel by controlling the output value, that is, the digital sensing current Isen, of the current sensing device 100 according to the current range that includes the estimated driving current. For example, when the estimated driving current is included in the low current range, the current sensing device 100 may accurately detect the fine variation of the driving current by highly controlling the integral gain of the integrator.

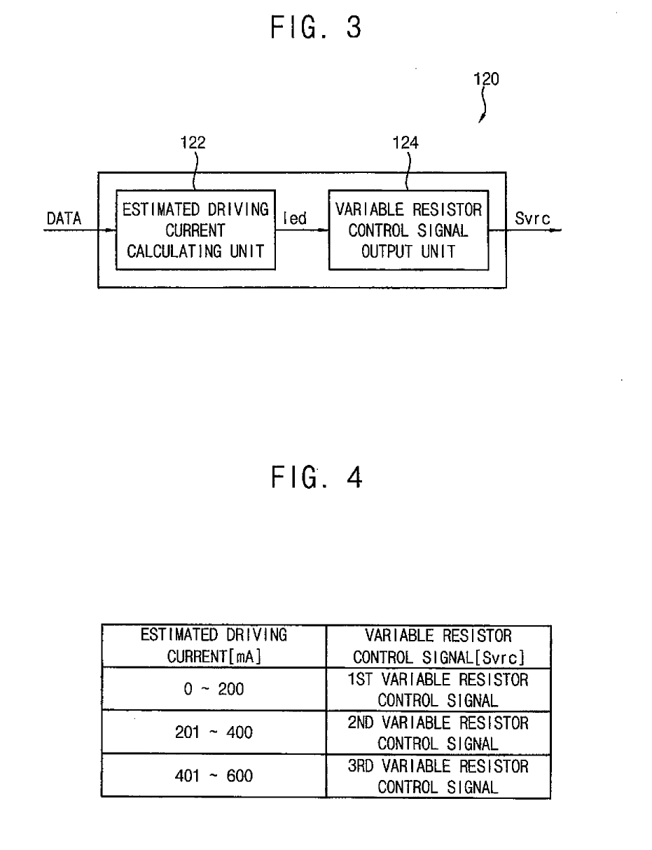

FIG. 3 is a variable resistor control unit that is included in the current sensing device of FIG. 1 and FIG. 4 is a diagram illustrating an example of a lookup table that is included in the variable resistor control unit of FIG. 3.

The variable resistor control unit 120 may include the estimated driving current calculating unit 122 and the variable resistor control signal output unit 124. The estimated driving current calculating unit 122 may calculate the estimated driving current led of the image data DATA per frame. For example, the estimated driving current calculating unit 122 may calculate the estimated driving current led according to a grayscale value of the image data DATA. A method of calculating the estimated driving current led may be changed by a size of the display panel, a resolution of the display panel, an arrangement of the line formed on the display panel, a length of the line formed on the display panel, etc. The variable resistor control signal output unit 124 may receive the estimated driving current led output from the estimated driving current calculating unit 122, and output the variable resistor control signal Svrc corresponding to the current range that includes the estimated driving current led. The variable resistor control signal output unit 124 may include the lookup table that stores the variable resistor control signal Svrc corresponding to the current range that includes the estimated driving current led. For example, when the driving current that is 0 mA through 600 mA flows through pixels, the variable resistor control signal output unit 124 may include the lookup table illustrated in FIG. 4. Referring to FIG. 4, when the estimated driving current led is included in the range of 0 mA through 200 mA, the variable resistor control unit 120 may output a first variable resistor control signal Svrc1. When the estimated driving current led is included in the range of 201 mA through 400 mA, the variable resistor control unit 120 may output a second variable resistor control signal Svrc2. When the estimated driving current led is included in the range of 401 mA through 600 mA, the variable resistor control unit 120 may output a third variable resistor control signal Svrc3. Each of the first through third variable resistor control signals Svrc1 through Svrc3 may be output to the sensing voltage calculating unit 160. The first through third variable resistor control signal Svrc1 through Svrc3 may respectively change the resistance of the third resistor R3 that is implemented as the variable resistor. The integral gain of the integrator 162 may be changed according to the resistance of the third resistor R3. The output value, that is, the digital sensing current Isen of the sensing voltage calculating unit 160 may be changed based on the integral gain.

As described above, the variable resistor control unit 120 may calculate the estimated driving current led and output the variable resistor control signal Svrc corresponding to the current range that includes the estimated driving current led. Here, the variable resistor control signal Svrc corresponding to the current range that includes the estimated driving current led may be stored in the lookup table 126. It should be understood that the lookup table can be implemented by any storage device capable of storing the load amount corresponding to the digital signals.

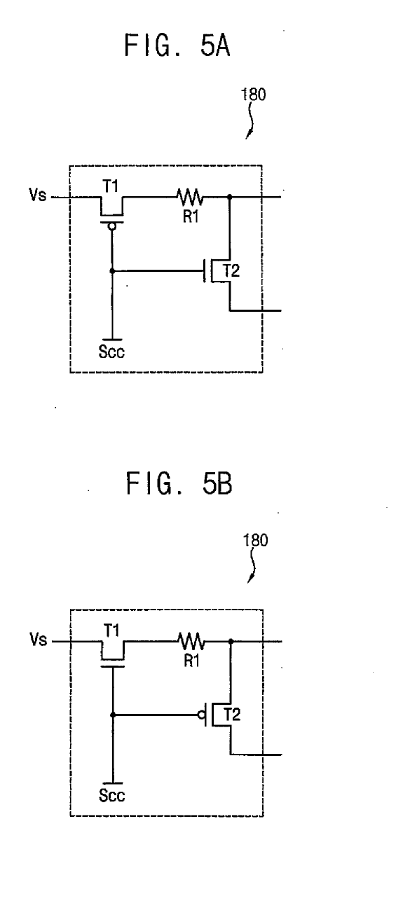

FIGS. 5A and 5B are circuit diagrams illustrating examples of a calculating control unit that is included in the current sensing device of FIG. 1.

Referring to FIGS. 5A and 5B, the calculating control unit 180 may include the first switching transistor T1 that transmits the sensing voltage Vs to the sensing voltage calculating unit 160 in response to the calculating control signal Scc and the second switching transistor T2 that discharge the capacitor C of the sensing voltage calculating unit 160 in response to the calculating control signal Scc. In some example embodiments, when the first switching transistor T1 turns on, the sensing voltage Vs may be transmitted to the sensing voltage calculating unit 160 and be integrated by the integral gain. Here, the second switching transistor T2 may turns off. In other example embodiments, when the second switching transistor T2 turns on, the capacitor C of the sensing voltage calculating unit 160 may be discharged. Here, the first switching transistor T1 may turns off.

As illustrated in FIG. 5A, the first switching transistor T1 may be implemented as a p-channel metal oxide semiconductor (PMOS) transistor and the second switching transistor T2 may be implemented as an n-channel metal oxide semiconductor (NMOS) transistor. Here, when the calculating control signal Scc that has a logic low level is provided, the sensing voltage Vs may be integrated by the integral gain. Further, when the calculating control signal Scc that has a logic high level is provided, the capacitor C of the sensing voltage calculating unit 160 may be discharged.

As illustrated in FIG. 5B, the first switching transistor T1 may be implemented as the NMOS transistor and the second switching transistor T2 may be implemented as the PMOS transistor. Here, when the calculating control signal Scc that has a logic high level is provided, the sensing voltage Vs may be integrated by the integral gain. Further, when the calculating control signal Scc that has a logic low level is provided, the capacitor C of the sensing voltage calculating unit 160 may be discharged.

As described, the calculating control unit 180 may control an operation of the sensing control calculating unit 160 according to the calculating control signal Scc. Although the calculating control unit 180 that includes the first switching transistor T1 and the second switching transistor T2 is described in FIGS. 5A and 5B, a composition of the calculating control unit 180 is not limited thereto. For example, the calculating control unit 180 may include switching elements that transmit the sensing voltage Vs of the calculating control unit 180 to the sensing voltage calculating unit 160 or discharge the capacitor C of the sensing voltage calculating unit 160 according to the calculating control signal Vcc.

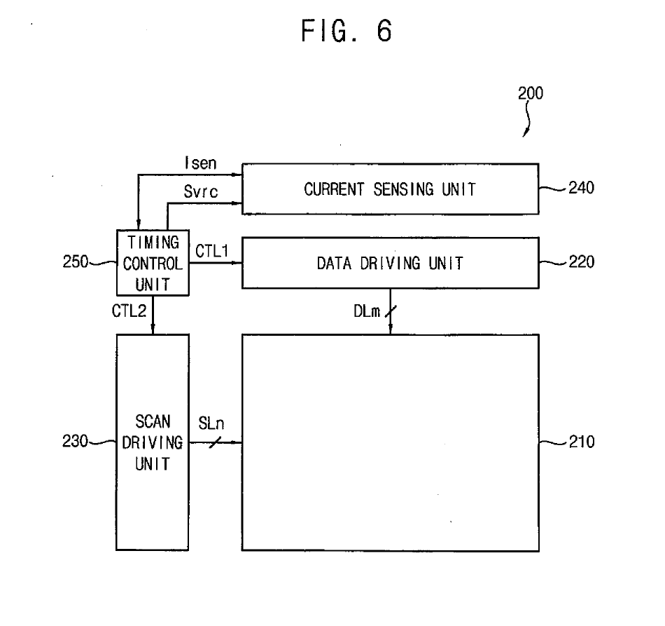

FIG. 6 is a block diagram illustrating an organic light emitting display device according to example embodiments.

Referring to FIG. 6, the organic light emitting display device 200 may include a display panel 210, a data driving unit 220, a scan driving unit 230, a current sensing unit 240, and a timing control unit 250. Here, the current sensing unit 240 may correspond to the current sensing device 100 of FIG. 1.

The display panel 210 may include a plurality of pixels. In some example embodiments, each pixel Px may include a pixel circuit, a driving transistor, and an organic light emitting diode. In this case, the pixel circuit may operate to provide a data signal, where the data signal is provided via data-lines DLm, to the driving transistor based on a scan signal, where the scan signal is provided via scan-lines SLn. The driving transistor may control a current flowing through the organic light emitting diode based on the data signal, and the organic light emitting diode may emit light based on the current.

The scan driving unit 230 may provide a scan signal to the pixels via the plurality of scan lines SLn. The data driving unit may provide a data signal to the pixels via the plurality of data lines DLm according to the scan signal. The timing control unit 250 may control the scan driving unit 230, the data driving unit by generating a plurality of control signals CTL1, CTL2. In some example embodiments, the current sensing unit 240 may be disposed in the timing control unit 250. In other example embodiments, the current sensing unit 240 may be coupled to the timing control unit 250.

The current sensing unit 240 may receive image data to be displayed on the display panel 210 and calculate an estimated driving current flowing through the pixels based on the image data. Further, the current sensing unit 240 may detect a sensing voltage corresponding to a driving current flowing through the pixels when the image data is displayed on the display panel 210 and calculate the sensing voltage by changing an integral gain according to a current range that includes the estimated driving current.

Specifically, the current sensing unit 240 may include a variable resistor unit, a current sensing unit, a sensing voltage calculating unit, and a calculating control unit. The variable resistor control unit may receive the image data that will be displayed on the display panel 210, calculate an estimated driving current flowing through the plurality of pixels included in the display panel 210 based on the image data, and output a variable resistor control signal Svrc corresponding to a current range that includes the estimated driving current. The variable resistor control unit may include the estimated driving current calculating unit and the variable resistor control signal output unit.

The estimated driving current calculating unit may calculate the estimated driving current of the image data per frame. For example, the estimated driving current calculating unit may calculate the estimated driving current according to a grayscale value of the image data. The variable resistor control signal output unit may receive the estimated driving current output from the estimated driving current calculating unit, and output the variable resistor control signal Svrc corresponding to the current range that includes the estimated driving current. The variable resistor control signal output unit may include the lookup table that stores the variable resistor control signal Svrc corresponding to the current range that includes the estimated driving current.

The current sensing unit may sense the driving current provided to the pixels while the image data is displayed on the display panel 210 and output a sensing voltage corresponding to the driving current. The current sensing unit may generate a detecting voltage corresponding to the driving current provided to the pixels while the image data is displayed on the display panel 210, amplify the detecting voltage, and output the amplified detecting voltage as the sensing voltage. The current sensing unit may include a detecting resistor and an amplifier. The detecting resistor may generate a detecting voltage corresponding to the driving current flowing through pixels. The amplifier may amplify the detecting voltage and output the amplified detecting voltage as the sensing voltage. The sensing voltage may be provided to the sensing voltage calculating unit through the calculating control unit.

The sensing voltage calculating unit may change an integral gain of an integrator according to the variable resistor control signal Svrc and integrates the sensing voltage Vs. The sensing voltage calculating unit may include the integrator, a first resistor, a second resistor, a third resistor, a fourth resistor, and a capacitor. The integral gain of the integrator may be controlled by the first through fourth resistors and the capacitor as descript in the equation 1. Here, the third resistor may be implemented as a digital variable resistor. A resistance of the third resistor may be changed according to the variable resistor control signal Svrc. The integral gain of the integrator may be changed as the resistance of the third resistor is changed. The sensing voltage output from the current sensing unit may be integrated based on the integral gain. The sensing voltage calculating unit may further include an analog-digital converter. The analog-digital converter may convert the output voltage from the integrator into a digital sensing current Isen.

The calculating control unit may control an operation of the sensing voltage calculating unit in response to a calculating control signal. The calculating control unit may include a first switching transistor that transmits the sensing voltage output from the current sensing unit in response to the calculating control signal into the sensing voltage calculating unit and a second switching transistor that discharges the capacitor of the sensing voltage calculating unit in response to the calculating control signal. In some example embodiments, when the first switching transistor turns on, the sensing voltage may be transmitted to the sensing voltage calculating unit and be integrated by the integral gain. Here, the second switching transistor may turn off. In other example embodiments, when the second switching transistor turns off, the capacitor of the sensing voltage calculating unit may be discharged. Here, the first switching transistor may turn off.

As described above, the organic light emitting display device 200 that includes the current sensing unit 240 may calculate the estimated driving current flowing through the pixels based on the image data that will be displayed on the display panel 210 and change the integral gain of the integrator according to the current range that includes the estimated driving current. Therefore, the current sensing unit 240 of the organic light emitting display device 200 according to example embodiments may accurately detect the variation of the driving current flowing through the pixels when the image data is displayed on the display panel 210 by controlling the output value, that is, the digital sensing current Isen of the current sensing unit 240 according to the current range that includes the estimated driving current. For example, when the estimated driving current is included in the low current range, the current sensing unit 240 may accurately detect the fine variation of the driving current by controlling the output value of the current sensing unit 240 although the variation of the driving current is small.

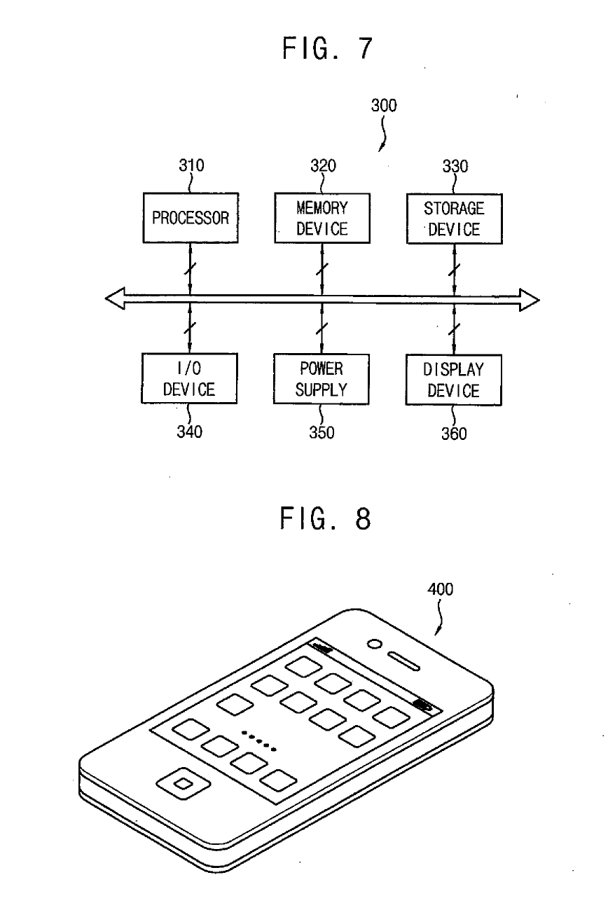

FIG. 7 is a block diagram illustrating an electronic device that includes the organic light emitting display device of FIG. 6 and FIG. 8 is a diagram illustrating an example of the electronic device that is implemented as a smart phone.

Referring to FIGS. 7 and 8, an electronic device 300 may include a processor 310, a memory device 320, a storage device 330, an input/output (I/O) device 340, a power supply 350, and a display device 360. Here, the display device 360 may correspond to the display device 200 of FIG. 5. In addition, the electronic device 300 may further include a plurality of ports for communicating a video card, a sound card, a memory card, a universal serial bus (USB) device, other electronic device, etc. Although it is illustrated in FIG. 7 that the electronic device 300 is implemented as a smart-phone 400, the electronic device 300 is not limited thereto.

The processor 310 may perform various computing functions. The processor 310 may be a microprocessor, a central processing unit (CPU), etc. The processor 310 may be coupled to other components via an address bus, a control bus, a data bus, etc. Further, the processor 310 may be coupled to an extended bus such as peripheral component interconnect (PCI) bus. The memory device 320 may store data for operations of the electronic device 300. For example, the memory device 320 may include at least one non-volatile memory device such as an erasable programmable read-only memory (EPROM) device, an electrically erasable programmable read-only memory (EEPROM) device, a flash memory device, a phase change random access memory (PRAM) device, a resistance random access memory (RRAM) device, a nano floating gate memory (NFGM) device, a polymer random access memory (PoRAM) device, a magnetic random access memory (MRAM) device, a ferroelectric random access memory (FRAM) device, etc, and/or at least one volatile memory device such as a dynamic random access memory (DRAM) device, a static random access memory (SRAM) device, a mobile DRAM device, etc. The storage device 330 may be a solid state drive (SSD) device, a hard disk drive (HDD) device, a CD-ROM device, etc.

The I/O device 340 may be an input device such as a keyboard, a keypad, a touchpad, a touch-screen, a mouse, etc, and an output device such as a printer, a speaker, etc. In some example embodiments, the display device 360 may be included in the I/O device 340. The power supply 350 may provide a power for operations of the electronic device 300.

The display device 360 may communicate with other components via the buses or other communication links. As described above, the display device 360 may include a display panel, a data driving unit, a scan driving unit, a timing control unit and current sensing unit. The display panel may include a plurality of pixels, and each of the pixels may emit light based on the current. The scan driving unit may provide a scan signal to the pixels, and the data driving unit may provide a data signal according to the scan signal.

The timing control unit may control the scan driving unit and the data driving unit. The current sensing unit may receive image data to be displayed on the display panel and calculate an estimated driving current flowing through the pixels of the display panel based on the image data. The current sensing unit may detect a sensing voltage corresponding to the driving current flowing through the pixels when the image data is displayed on the display panel and calculate the sensing voltage by controlling an integral gain of an integrator based on the estimated driving current.

For example, the current sensing unit may include a variable resistor control unit, a current sensing unit, a sensing voltage calculating unit, and a calculating control unit. The variable resistor control unit may receive the image data that will be displayed on the display panel, calculate the estimated driving current flowing through the pixels based on the image data, and output a variable resistor control signal corresponding to a current range that includes the estimated driving current.

The variable resistor control unit may store the variable resistor control signal corresponding to the current range that includes the estimated driving current in a lookup table. The current sensing unit may include a detecting resistor and an amplifier. The detecting resistor may generate a detecting voltage corresponding to the driving current provided to the pixels when the image data is displayed on the display panel. The amplifier may amplify the detecting voltage and output the amplified detecting voltage as the sensing voltage.

The sensing voltage may be provided to the sensing voltage calculating unit. The sensing voltage calculating unit may change the integral gain of the integrator according to the variable resistor control signal and integrate the sensing voltage. The integral gain of the integrator may be determined by first through fourth resistors and capacitor.

Here, the third resistor may be implemented as a digital variable resistor. The resistance of the third resistor may be controlled by the variable resistor control signal. The integral gain of the integrator may be changed according to the resistance of the third resistor. The sensing voltage may be integrated by the integrator. The calculating control unit may include a first switching transistor that transmit the sensing voltage output from the current sensing unit to the sensing voltage calculating unit in response to a calculating control signal and a second switching transistor that discharge the capacitor of the sensing voltage calculating unit in response to the calculating control signal.

In some example embodiments, when the first switching transistor turns on, the sensing voltage may be transmitted to the sensing voltage calculating unit and be integrated by the integral gain. Here, the second switching transistor may turn off. In other example embodiments, when the second switching transistor turns on, the capacitor of the sensing voltage calculating unit may be discharged. Here, the first switching transistor may turn off.

As described above, the electronic device 300 according to example embodiments may include the display device having the current sensing unit. The current sensing unit may calculate the estimated driving current flowing through the pixels based on the image data to be displayed on the display panel and change the integral gain of the integrator according to the current range that includes the estimated driving current. Therefore, the electronic device 300 according to example embodiments may accurately detect the variation of the driving current flowing through the pixels when the image data is displayed on the display panel by controlling the output, that is, the digital sensing current Isen of the current sensing unit according to the current range that includes the driving current. For example, when the driving current is included in the low current range, the current sensing unit may accurately detect the fine variation of the driving current by controlling the output value of the current sensing unit although the variation of the driving current is small.

Embodiments of the present invention may be applied to an electronic device having a display device. For example, embodiments of the present invention may be applied to a computer monitor, a laptop, a digital camera, a cellular phone, a smart phone, a smart pad, a television, a personal digital assistant (PDA), a portable multimedia player (PMP), a MP3 player, a navigation system, a game console, a video phone, etc.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims, and their equivalents.

What is claimed is:

1. A current sensing device of a display panel, the current sensing device comprising:
a variable resistor control unit configured to:
receive image data to be displayed on the display panel;
calculate an estimated driving current flowing through a plurality of pixels included in the display panel based on the image data; and
output a variable resistor control signal corresponding to a current range comprising the estimated driving current;
a current sensing unit configured to sense a driving current provided to the pixels while the image data is displayed on the display panel and to output a sensing voltage corresponding to the driving current;
a sensing voltage calculating unit configured to change an integral gain according to the variable resistor control signal and to integrate the sensing voltage; and
a calculating control unit configured to control an operation of the sensing voltage calculating unit in response to a calculating control signal.

2. The current sensing device of claim 1, wherein the sensing voltage calculating unit comprises:
an integrator comprising:
a first input terminal;
a second input terminal; and
an output terminal;
a first resistor between the calculating control unit and the first input terminal;
a second resistor between the first input terminal and the output terminal;
a third resistor between the second input terminal and a ground connection and implemented as a digital variable resistor;
a fourth resistor between the second input terminal and the output terminal; and
a capacitor between the first input terminal and the ground connection.

3. The current sensing device of claim 2, wherein a resistance of the third resistor is changed according to the variable resistor control signal.

4. The current sensing device of claim 2, wherein the calculating control unit comprises:
a first switching transistor configured to transmit the sensing voltage to the sensing voltage calculating unit in response to the calculating control signal; and
a second switching transistor configured to discharge the capacitor in response to the calculating control signal.

5. The current sensing device of claim 4, wherein the first switching transistor is implemented as a P-channel Metal Oxide Semiconductor (PMOS) transistor, and
wherein the second switching transistor is implemented as an N-channel Metal Oxide Semiconductor (NMOS) transistor.

6. The current sensing device of claim 5, wherein the sensing voltage is integrated based on the integral gain when the calculating control signal having a logic low level is provided, and
wherein the capacitor is discharged when the calculating control signal having a logic high level is provided.

7. The current sensing device of claim 4, wherein the first switching transistor is implemented as an N-channel Metal Oxide Semiconductor (NMOS) transistor, and
wherein the second switching transistor is implemented as a P-channel Metal Oxide Semiconductor (PMOS) transistor.

8. The current sensing device of claim 7, wherein the sensing voltage is integrated based on the integral gain when the calculating control signal having a logic high level is provided, and
wherein the capacitor is discharged when the calculating control signal having a logic low level is provided.

9. The current sensing device of claim 1, wherein the variable resistor control unit comprises:
an estimated driving current calculating unit configured to calculate the estimated driving current of the image data per frame; and
a variable resistor control signal output unit configured to output the variable resistor control signal corresponding to the current range that comprises the estimated driving current.

10. The current sensing device of claim 9, wherein the variable resistor control signal output unit comprises a lookup table that stores the variable resistor control signal corresponding to the current range that comprises the estimated driving current.

11. The current sensing device of claim 1, wherein the current sensing unit comprises:
a detecting resistor configured to generate a detecting voltage corresponding to the driving current provided to the pixels; and
an amplifier configured to amplify the detecting voltage to output an amplified detecting voltage as the sensing voltage.

12. An organic light emitting display device comprising:
a display panel comprising a plurality of pixels;
a data driving unit configured to provide a data signal to the display panel;
a scan driving unit configured to provide a scan signal to the display panel;
a current sensing unit configured to:
calculate an estimated driving current flowing through the pixels based on image data to be displayed on the display panel;
detect a sensing voltage corresponding to a driving current flowing through the pixels while the image data is displayed on the display panel; and
calculate the sensing voltage by changing an integral gain according to a current range comprising the estimated driving current; and
a timing control unit configured to control the data driving unit, the scan driving unit, and the current sensing unit.

13. The display device of claim 12, wherein the current sensing unit comprises:
a variable resistor control unit configured to:
receive the image data to be displayed on the display panel;
calculate the estimated driving current flowing through the pixels based on the image data; and
output a variable resistor control signal corresponding to the current range comprising the estimated driving current;
a current sensing unit configured to sense the driving current provided to the pixels while the image data is displayed on the display panel and to output the sensing voltage corresponding to the driving current;
a sensing voltage calculating unit configured to change the integral gain according to the variable resistor control signal and to integrate the sensing voltage; and
a calculating control unit configured to control an operation of the sensing voltage calculating unit in response to a calculating control signal.

14. The display device of claim 13, wherein the sensing voltage calculating unit comprises:
an integrator comprising a first input terminal, a second input terminal, and an output terminal;
a first resistor coupled between the calculating control unit and the first input terminal;
a second resistor coupled between the first input terminal and the output terminal;
a third resistor coupled between the second input terminal and a ground connection and implemented as a digital variable resistor;
a fourth resistor coupled between the second input terminal and the output terminal; and
a capacitor coupled between the first input terminal and the ground connection.

15. The display device of claim 14, wherein a resistance of the third resistor is changed according to the variable resistor control signal.

16. The display device of claim 14, wherein the calculating control unit comprises:
a first switching transistor configured to transmit the sensing voltage to the sensing voltage calculating unit in response to the calculating control signal; and
a second switching transistor configured to discharge the capacitor in response to the calculating control signal.

17. The display device of claim 13, wherein the variable resistor control unit comprises:
an estimated driving current calculating unit configured to calculate the estimated driving current of the image data per frame; and
a variable resistor control signal output unit configured to output the variable resistor control signal corresponding to the current range that comprises the estimated driving current.

18. The display device of claim 17, wherein the variable resistor control signal output unit comprises a lookup table that stores the variable resistor control signal corresponding to the current range comprising the estimated driving current.

19. The display device of claim 13, wherein the current sensing unit comprises:
a detecting resistor configured to generate a detecting voltage corresponding to the driving current provided to the pixels; and
an amplifier configured to amplify the detecting voltage to output an amplified detecting voltage as the sensing voltage.

20. The display device of claim 12, wherein the current sensing unit is coupled to the timing control unit or is included in the timing control unit.
